(19) United States
(12) Patent Application Publication
(10) Pub. No.: US 2010/0085258 A1
(43) Pub. Date: Apr. 8, 2010

(54) ELECTRICAL CIRCUIT MATERIAL, ANTENNA DEVICE AND METHOD FOR MANUFACTURING ELECTRICAL CIRCUIT MATERIAL

(75) Inventors: MASAO TESHIMA, TOKYO (JP); HIROSHI SHIMASAKI, TOKYO (JP); HIROYUKI HOTTA, TOKYO (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: KABUSHIKI KAISHA TOSHIBA, Tokyo (JP)

(21) Appl. No.: 12/475,817

(22) Filed: Jun. 1, 2009

(30) Foreign Application Priority Data
Oct. 3, 2008 (JP) 2008-258824

(51) Int. Cl. H01Q 1/38; H05K 1/00; B29C 53/40

(52) U.S. Cl. 343/700 MS; 174/254; 156/217

(57) ABSTRACT

An electrical circuit material including a substrate and a bend section is provided. The substrate is formed to be planar. The substrate has a first face and a second face being back to back each other. The first face is provided with a first conductive pattern. The bend section is formed by a planar flexible material being bent or rounded and having a third face and a fourth face being back to back each other. The third face is provided with a second conductive pattern. The bend section is arranged with the substrate in such a way that a portion of the third face being in contact with the first face of the substrate and that the second conductive pattern is connected to the first conductive pattern.

### CROSS REFERENCE TO RELATED APPLICATIONS

This application is based upon and claims the benefit of priority from the prior Japanese Patent Application No. 2008-258824 filed on Oct. 3, 2008;

the entire contents of which are incorporated herein by reference.

### BACKGROUND OF THE INVENTION

1. Field of the Invention

The Present Invention relates to an electrical circuit material, an antenna device and a method for manufacturing an electrical circuit material, and in particular to those adapted for a radio apparatus.

2. Description of the Related Art

It is generally known that a radio apparatus, e.g., a mobile phone, lately has a built-in antenna device contained in a housing instead of an antenna device configured to extend to the outside of the housing such as a whip antenna that used to be widely used. Technologies such as soldering a metal plate constituting an antenna element or a chip antenna to a printed board, utilizing a conductive pattern of a printed board as an antenna element, fixing a nonconductive material having a surface on which an antenna element is formed to a printed board or a housing, plating a housing with a conductive pattern constituting an antenna element and so on are known as methods for manufacturing or mounting a built-in antenna device.

One of such technologies is integrating an antenna element onto a printed board and bending a portion of the printed board so as to increase a gain for an electromagnetic wave polarized vertically to a face of the printed board, as disclosed in Japanese Patent Publication of Unexamined Applications (Kokai), No. 2004-111563.

According to JP 2004-111563, a plurality of conductive patterns are layered while being separated by insulating material formed by thermoplastic resin so as to form a multilayer printed board having a mother board portion and an antenna portion. The number of the layers of the mother board portion is different from the number of the layers of the antenna portion. The antenna portion extends from the mother board portion and is bent.

The antenna of JP 2004-111563 is so configured that some and not all of the layers of the mother board portion of the multilayer printed board extend from the mother board portion and are bent so as to form the antenna portion. Thus, the antenna of JP 2004-111563 requires a special multilayer printed board that partially varies in the number of the layers. It is supposed that the layers are inter-connected to each other through via holes. In some cases, the above aspects may cause a problem in that cost reduction of the printed board is difficult.

### SUMMARY OF THE INVENTION

Accordingly, an object of the present invention is to simplify processing of an electrical circuit material that can be used as a built-in antenna, and to simplify interconnections of the electrical circuit material.

To achieve the above object, according to one aspect of the present invention, an electrical circuit material including a substrate and a bend section is provided. The substrate is formed to be planar. The substrate has a first face and a second face being back to back each other. The first face is provided with a first conductive pattern. The bend section is formed by a planar flexible material being bent or rounded and having a third face and a fourth face being back to back each other. The third face is provided with a second conductive pattern. The bend section is arranged with the substrate in such a way that a portion of the third face being in contact with the first face of the substrate and that the second conductive pattern is connected to the first conductive pattern.

### BRIEF DESCRIPTION OF THE DRAWINGS

FIG. 1 is a perspective view showing a configuration of an antenna device of a first embodiment of the present invention.

FIG. 2 is a developed view showing the configuration of the antenna device of the first embodiment.

FIG. 3 shows a connection between a first conductive pattern and a second conductive pattern of the antenna device of the first embodiment.

FIG. 4 is a perspective view showing a configuration of an antenna device of a second embodiment of the present invention.

FIG. 5 is a developed view showing the configuration of the antenna device of the second embodiment.

FIG. 6 shows a connection between a first conductive pattern and a second conductive pattern of the antenna device of the second embodiment.

FIG. 7 is a perspective view showing a configuration of an antenna device of a third embodiment of the present invention.

FIG. 8 is a developed view showing the configuration of the antenna device of the third embodiment.

FIG. 9 is a perspective view showing a configuration of an antenna device of a first modification included in a fourth embodiment of the present invention.

FIG. 10 is a perspective view showing a configuration of an antenna device of a second modification included in the fourth embodiment.

FIG. 11 is a perspective view showing a configuration of an antenna device of a third modification included in the fourth embodiment.

FIG. 12 is a perspective view showing a configuration of an antenna device of a fourth modification included in the fourth embodiment.

FIGS. 13A-13F show other modifications of bend sections or substrates of the first to fourth embodiments of the present invention.

### DETAILED DESCRIPTION OF THE INVENTION

Hereinafter, embodiments of the present invention will be described in detail. In following descriptions, terms such as upper, lower, left, right, horizontal or vertical used while referring to a drawing shall be interpreted on a page of the drawing unless otherwise noted. A same reference numeral given in no less than two drawings shall represent a same member or a same portion.

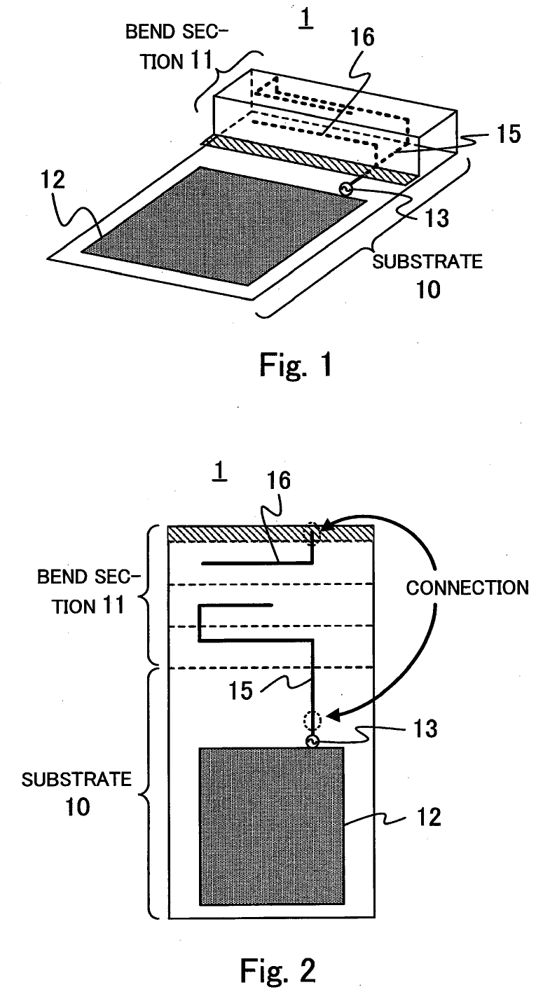

A first embodiment of the present invention will be described with reference to FIGS. 1-3. FIG. 1 and FIG. 2 are a perspective view and a developed view, respectively, showing a configuration of an antenna device 1 of the first embodiment of the present invention. The antenna device 1 has a substrate 10 and a bend section 11. The substrate 10 and the bend section 11 are formed by one planar flexible material. The bend section 11 is formed in such a way that a portion of the substrate 10 including an upper end shown in FIG. 2 is bent along four horizontal dashed lines.

As shown in FIG. 2, the substrate 10 and the bend section 11 are upper and lower portions with respect to the lowest horizontal dashed line, respectively. The flexible material described above can be selected from, e.g., thermoplastic resin (or liquid crystal polymer) materials.

A front face of the substrate 10 on the page of FIG. 2 is called an upper face, and a back of the upper face that is not shown in FIG. 2 is called a lower face. The substrate 10 is provided on the upper face with a grounded conductor 12 (its shape shown in FIG. 2 is an example). The grounded conductor 12 is provided on a side thereof with a feeding portion 13 that is connected to a radio circuit provided in the substrate 10 but not shown in FIG. 2. The substrate 10 is provided on the upper face with a first conductive pattern 15 that is connected to the feeding portion 13.

A front face of the bend section 11 on the page of FIG. 2 faces the inside of the bend section 11 and is called an inner face of the bend section 11. As obviously shown in FIG. 1 and FIG. 2, the inner face of the bend section 11 continues from the upper face of the substrate 10. The first conductive pattern 15 extends from the upper face of the substrate 10 to the inner face of the bend section 11 and reaches an open end.

A back of the inner face of the bend section 11 that is not shown in FIG. 2 faces the outside of the bend section 11 and is called an outer face of the bend section 11. As obviously shown in FIG. 1 and FIG. 2, the outer face of the bend section 11 continues from the lower face of the substrate 10.

As shown in FIGS. 1 and 2, an upper portion of the bend section 11 with respect to the highest horizontal dashed line (indicated by diagonal hatching) is bent towards the outside of space surrounded by the bend section 11. The inner face of the portion of the bend section 11 indicated by the hatching is in contact with the upper face of the substrate 10.

The bend section 11 is provided on the front portion of the inner face in FIG. 1 with a second conductive pattern 16 being invisible and thus shown by a dotted line in FIG. 1. As the inner face of the bend section 11 is visible in FIG. 2, the second conductive pattern 16 is shown by a solid line.

If the bend section 11 is bent along the four horizontal dashed lines, as shown in FIG. 2, a portion of the second conductive pattern 16 included in the portion of the bend section 11 indicated by the diagonal hatching comes to a position where it can be connected to a portion of the first conductive pattern 15 being close to the feeding portion 13. Thus, if the portion of the bend section 11 indicated by the diagonal hatching is, e.g., crimped on the upper face of the substrate 10, one end of the second conductive pattern 16 can be connected to the first conductive pattern 15. Another end of the second conductive pattern 16 is open.

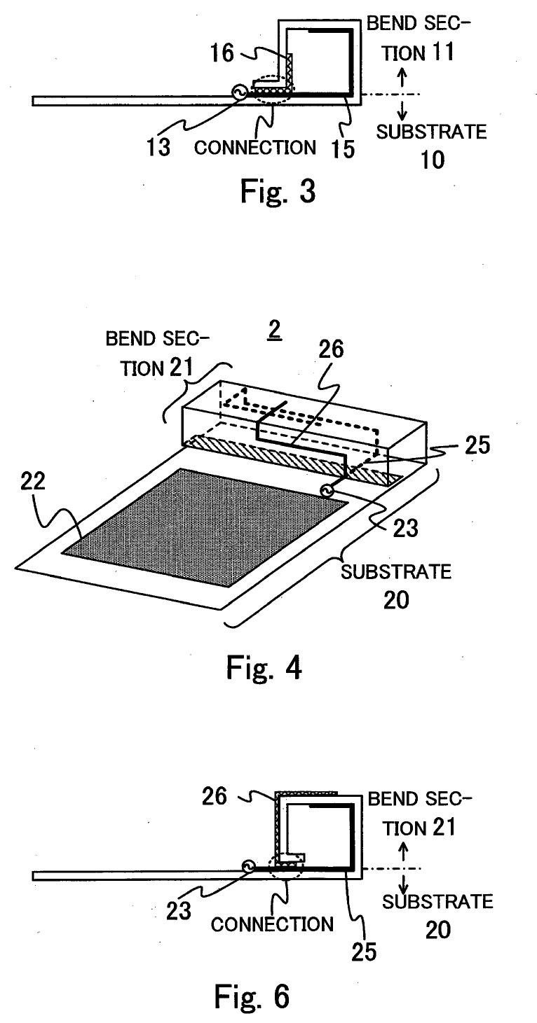

FIG. 3 shows a connection between the second conductive pattern 16 and the first conductive pattern 15 described above as viewed from a right-hand side in FIG. 1 or FIG. 2. FIG. 3 shows a state in which the portion of the bend section 11 indicated by the diagonal hatching in FIG. 1 or FIG. 2 is bent towards the outside of the space surrounded by the bend section 11, and the first conductive pattern 15 and the second conductive pattern 16 are connected to each other in an area indicated by a dotted ellipse.

As described above, the antenna device 1 is so configured that an open-ended antenna element constituted by the first conductive pattern 15 is connected to the feeding portion 13, and that another open-ended antenna element constituted by the second conductive pattern 16 is branched off from a portion being closest to the feeding portion 13. That is, the antenna device 1 is configured as a multiple-resonant antenna having the feeding portion 13 in common.

Although the material forming the substrate 10 and the bend section 11 may be a multilayer material or a single-layer material, one having fewer layers is advantageous from a viewpoint of flexibility. The first conductive pattern 15 and the second conductive pattern 16 can be connected by using a simple method such as being crimped on the faces in contact with each other, without a need of interconnection between the layers through via holes. Such configurations of the substrate 10 and the bend section 11 and the connection between the conductive patterns can be applied not only to an antenna, but widely to arrangement of elements and interconnections between the elements on an electrical circuit material formed by a substrate partially bent or rounded.

If a thin material is used for the substrate 10, the shape of the substrate 10 can be mechanically reinforced by bending or rounding the material and connecting different portions of the material to each other. The first embodiment of the present invention can simplify the manufacturing process of the electrical circuit material, and can thereby reduce cost in comparison with ordinary methods.

According to the first embodiment of the present invention, the electrical circuit material forms the bend section by partially bending or rounding the substrate, and the conductive patterns are provided on the surface of the bend section and are connected to each other, e.g., by being crimped at the portion where the substrate and the bend section are in contact with each other, so that the electrical circuit material that can be used as a built-in antenna can be provided.

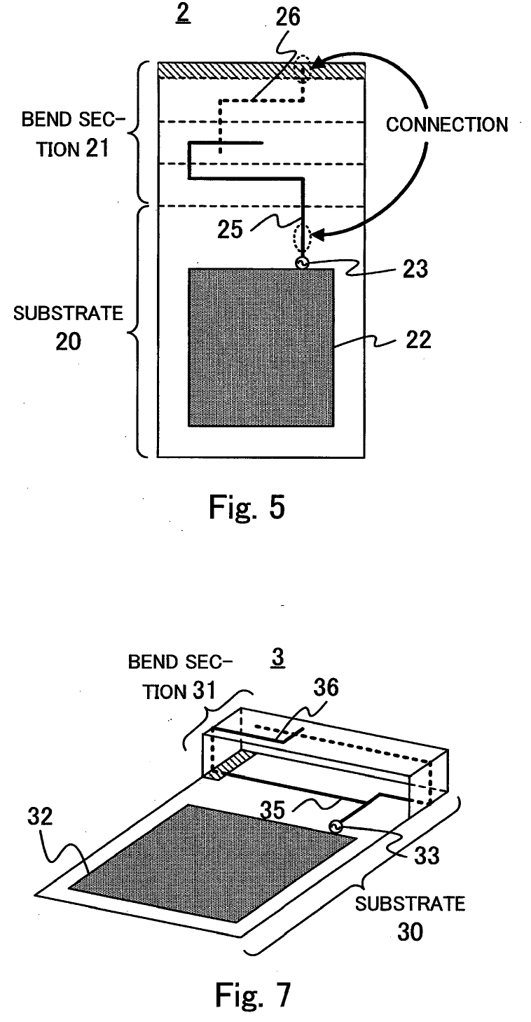

A second embodiment of the present invention will be described with reference to FIGS. 4-6. FIG. 4 and FIG. 5 are a perspective view and a developed view, respectively, showing a configuration of an antenna device 2 of the second embodiment of the present invention. The antenna device 2 has a substrate 20 and a bend section 21. The substrate 20 and the bend section 21 are formed by one planar flexible material. The bend section 21 is formed in such a way that a portion of the substrate 20 including an upper end shown in FIG. 5 is bent along four horizontal dashed lines.

As shown in FIG. 5, the substrate 20 and the bend section 21 are upper and lower portions with respect to the lowest horizontal dashed line, respectively. The flexible material described above can be selected similarly as that of the first embodiment.

A front face of the substrate 20 on the page of FIG. 5 is called an upper face, and a back of the upper face that is not shown in FIG. 5 is called a lower face. The substrate 20 is provided on the upper face with a grounded conductor 22 (its shape shown in FIG. 5 is an example). The grounded conductor 22 is provided on a side thereof a feeding portion 23 that is connected to a radio circuit provided in the substrate 20 but not shown in FIG. 5. The substrate 20 is provided on the upper face with a first conductive pattern 25 that is connected to the feeding portion 23.

A front face of the bend section 21 on the page of FIG. 5 faces the inside of the bend section 21 and is called an inner face of the bend section 21. As obviously shown in FIG. 4 and FIG. 5, the inner face of the bend section 21 continues from the upper face of the substrate 20. The first conductive pattern 25 extends from the upper face of the substrate 20 to the inner face of the bend section 21 and reaches an open end.

A back of the inner face of the bend section 21 that is not shown in FIG. 5 faces the outside of the bend section 21 and is called an outer face of the bend section 21. As obviously shown in FIG. 4 and FIG. 5, the outer face of the bend section 21 continues from the lower face of the substrate 20.

As shown in FIGS. 4 and 5, an upper portion of the bend section 21 with respect to the highest horizontal dashed line (indicated by diagonal hatching in FIG. 4 and FIG. 5) is bent towards the inside of space surrounded by the bend section 21. The outer face of the portion of the bend section 21 indicated by the hatching is in contact with the upper face of the substrate 20.

The bend section 21 is provided on the front and top portions of the inner face with a second conductive pattern 26 being visible and thus shown by a solid line in FIG. 4. As the outer face of the bend section 21 is invisible in FIG. 5, the second conductive pattern 26 is shown by a dotted line.

If the bend section 21 is bent along the four horizontal dashed lines, as shown in FIG. 5, a portion of the second conductive pattern 26 included in the portion of the bend section 21 indicated by the diagonal hatching comes to a position where it can be connected to a portion of the first conductive pattern 25 being close to the feeding portion 23. Thus, if the portion of the bend section 21 indicated by the diagonal hatching is, e.g., crimped on the upper face of the substrate 20, one end of the second conductive pattern 26 can be connected to the first conductive pattern 25. Another end of the second conductive pattern 26 is open.

FIG. 6 shows a connection between the second conductive pattern 26 and the first conductive pattern 25 described above as viewed from a right-hand side in FIG. 4 or FIG. 5. FIG. 6 shows a state in which the portion of the bend section 21 indicated by the diagonal hatching in FIG. 4 or FIG. 5 is bent towards the inside of the space surrounded by the bend section 21, and the first conductive pattern 25 and the second conductive pattern 26 are connected to each other in an area indicated by a dotted ellipse.

As described above, the antenna device 2 is so configured that an open-ended antenna element constituted by the first conductive pattern 25 is connected to the feeding portion 23, and that another open-ended antenna element constituted by the second conductive pattern 26 is branched off from a portion being close to the feeding portion 23. That is, the antenna device 2 is configured as a multiple-resonant antenna having the feeding portion 23 in common.

As described above, the second embodiment has an advantage similarly as the first embodiment in that the first conductive pattern 25 and the second conductive pattern 26 can be connected by using a simple method of, e.g., being crimped on the faces in contact with each other, without a need of interconnection between the layers through via holes. In addition, the second embodiment uses the conductive pattern 26 provided on the outer face of the bend section 21, and can thereby increase a degree of freedom of the wiring of the conductive patterns.

According to the second embodiment of the present invention described above, an additional effect can be obtained that a degree of freedom of the wiring of the conductive patterns can be increased.

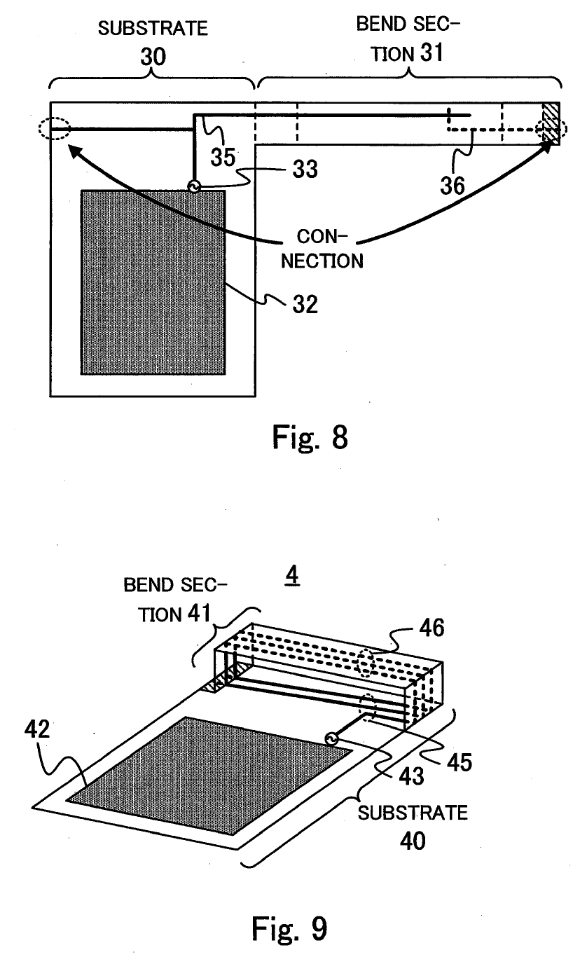

A third embodiment of the present invention will be described with reference to FIGS. 7 and 8. FIG. 7 and FIG. 8 are a perspective view and a developed view, respectively, showing a configuration of an antenna device 3 of the third embodiment of the present invention. The antenna device 3 has a substrate 30 and a bend section 31. The substrate 30 and the bend section 31 are formed by one planar flexible material. The bend section 31 is formed in such a way that a portion of the substrate 30 including an upper end shown in FIG. 8 is bent along four vertical dashed lines.

As shown in FIG. 8, the substrate 30 and the bend section 31 are left-hand side and right-hand side portions with respect to the most left vertical dashed line, respectively. The flexible material described above can be selected similarly as that of the first embodiment.

A front face of the substrate 30 on the page of FIG. 8 is called an upper face, and a back of the upper face that is not shown in FIG. 8 is called a lower face. The substrate 30 is provided on the upper face with a grounded conductor 32 (its shape shown in FIG. 8 is an example). The grounded conductor 32 is provided on a side thereof with a feeding portion 33 that is connected to a radio circuit provided in the substrate 30 but not shown in FIG. 8. The substrate 30 is provided on the upper face with a first conductive pattern 35 that is connected to the feeding portion 33.

A front face of the bend section 31 on the page of FIG. 8 faces the inside of the bend section 31 and is called an inner face of the bend section 31. As obviously shown in FIG. 7 and FIG. 8, the inner face of the bend section 31 continues from the upper face of the substrate 30. The first conductive pattern 35 extends from the upper face of the substrate 30 to the inner face of the bend section 31, then forks and reaches an open end and a left end of the substrate 30 on the right-hand side and on the left-hand side, respectively.

A back of the inner face of the bend section 31 that is not shown in FIG. 8 faces the outside of the bend section 31 and is called an outer face of the bend section 31. As obviously shown in FIG. 7 and FIG. 8, the outer face of the bend section 31 continues from the lower face of the substrate 30.

As shown in FIGS. 7 and 8, a right-hand portion of the bend section 31 with respect to the most right vertical dashed line (indicated by diagonal hatching) is bent towards the inside of space surrounded by the bend section 31. The outer face of the portion of the bend section 31 indicated by the hatching is in contact with the upper face of the substrate 30.

The bend section 31 is provided on the outer face with a second conductive pattern 36. In FIG. 7, the second conductive pattern 36 is shown by a dotted line and by a solid line on left (invisible) and top (visible) portions of the outer face of the bend section 31, respectively. As the outer face of the bend section 31 is invisible in FIG. 8, the second conductive pattern 36 is shown by a dotted line.

If the bend section 31 is bent along the four vertical dashed lines, as shown in FIG. 8, a portion of the second conductive pattern 36 included in the portion of the bend section 31 indicated by the diagonal hatching comes to a position where it can be connected to a portion of the first conductive pattern 35 being close to the left end of the substrate 30. Thus, if the portion of the bend section 31 indicated by the diagonal hatching is, e.g., crimped on the upper face of the substrate 30, the second conductive pattern 36 can be connected to the first conductive pattern 35. The first conductive pattern 35 can thereby be partially connected to the second conductive pattern 36 so that a required line length can be secured.

As described above, the antenna device 3 is so configured that both an open-ended antenna element constituted by a portion of the first conductive pattern 35 that branches off rightwards in FIG. 8 and an open-ended antenna element constituted by a portion of the first conductive pattern 35 that branches off leftwards in FIG. 8 and the second conductive pattern 36 are fed from the feeding portion 33. That is, the antenna device 3 is configured as a multiple-resonant antenna having the feeding portion 33 in common.

As described above, the third embodiment can simplify the manufacturing process of the electrical circuit material similarly as the first embodiment, and can provide the conductive patterns on both the inner and outer faces of the bend section similarly as the second embodiment. In addition, the third embodiment can link the conductive patterns of the substrate and of the bend section to each other so that a required line length is secured.

According to the third embodiment of the present invention described above, an additional effect can be obtained that the conductive patterns of the substrate and of the bend section can be linked to each other so that a required line length is secured.

A fourth embodiment of the present invention will be described with reference to FIGS. 9-13F. The fourth embodiment includes a plurality of modifications of the first to third embodiments described above. FIG. 9 is a perspective view showing a configuration of an antenna device 4 of a first modification included in the fourth embodiment. The antenna device 4 has a substrate 40 and a bend section 41. The substrate 40 and the bend section 41 are formed by one planar flexible material. The bend section 41 is formed in such a way that an end portion of the substrate 40 formed similarly as shown in FIG. 8 of the third embodiment is bent similarly as shown in FIGS. 7 and 8.

A distinction between the substrate 40 and the bend section 41, a definition of upper and lower faces of the substrate 40 and a definition of inner and outer faces of the bend section 41 are same as described with respect to the third embodiment. The portion of the bend section 41 indicated by diagonal hatching in FIG. 9 (corresponding to the portion of the bend section 31 of the third embodiment indicated by the diagonal hatching in FIGS. 7 and 8) is bent differently from the third embodiment, however, towards the outside of the space surrounded by the bend section 41. Thus, the inner face of the portion of the bend section 41 indicated by the hatching is in contact with the upper face of the substrate 40.

The substrate 40 is provided on the upper face with a grounded conductor 42 (its shape shown in FIG. 9 is an example). The grounded conductor 42 is provided on a side thereof with a feeding portion 43 that is connected to a radio circuit provided in the substrate 40 but not shown in FIG. 9. The substrate 40 is provided on the upper face with a first conductive pattern 45 that is connected to the feeding portion 43. As shown in FIG. 9, three of the first conductive patterns 45 in all are provided on the upper face of the substrate 40.

The bend section 41 is provided on the inner face with three of second conductive patterns 46 in all. The second conductive patterns 46 are shown in FIG. 9 by solid and dotted lines in visible and invisible portions, respectively, of the left, right and upper inner faces of the bend section 41.

The first conductive pattern 45 on the substrate 40 extends onto the bend section 41 at an interface between the substrate 40 and the bend section 41 positioned on a right-hand side in FIG. 9, so as to continue to the second conductive pattern 46. Meanwhile, if the bend section 41 is bent as shown in FIG. 9, a portion of the second conductive pattern 46 included in the portion of the bend section 41 indicated by the diagonal hatching comes to a position where it can be connected to a portion of the first conductive pattern 45 being close to the left end of the substrate 40. Thus, if the portion of the bend section 41 indicated by the diagonal hatching is, e.g., crimped on the upper face of the substrate 40, the second conductive pattern 46 can be connected to the first conductive pattern 45.

The first conductive patterns 45 and the second conductive patterns 46 consequently form a spiral line as a whole, and can work as a kind of helical antenna by being fed from the feeding portion 43.

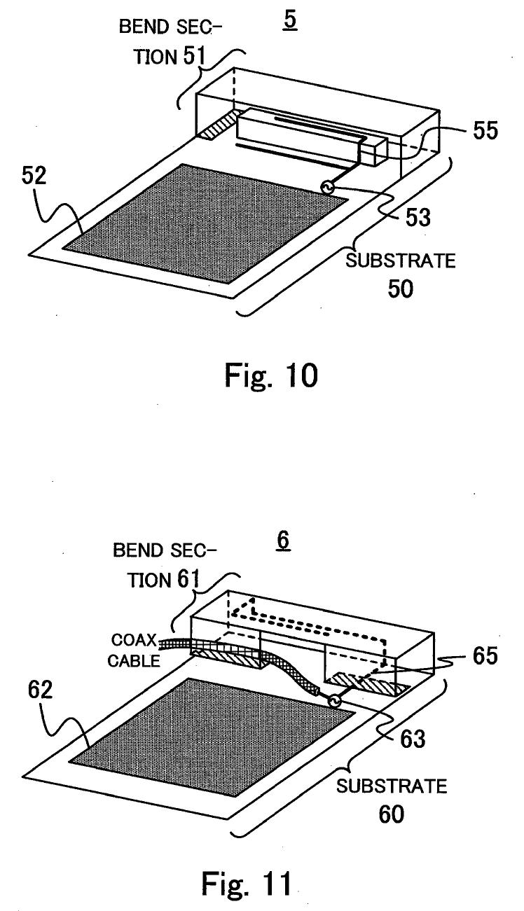

FIG. 10 is a perspective view showing a configuration of an antenna device 5 of a second modification included in the fourth embodiment. The antenna device 5 has a substrate 50 and a bend section 51. The substrate 50 and the bend section 51 are formed by one planar flexible material. The bend section 51 is formed in such a way that an end portion of the substrate 50 formed similarly as shown in FIG. 8 of the third embodiment is bent similarly as shown in FIGS. 7 and 8.

A distinction between the substrate 50 and the bend section 51, a definition of upper and lower faces of the substrate 50 and a definition of inner and outer faces of the bend section 51 are same as described with respect to the third embodiment. The portion of the bend section 51 indicated by diagonal hatching in FIG. 10 (corresponding to the portion of the bend section 31 of the third embodiment indicated by the diagonal hatching in FIGS. 7 and 8) is bent similarly as the third embodiment towards the inside of the space surrounded by the bend section 51. Thus, the outer face of the portion of the bend section 51 indicated by the hatching is in contact with the upper face of the substrate 50.

The substrate 50 is provided on the upper face with a grounded conductor 52 (its shape shown in FIG. 10 is an example). The grounded conductor 52 is provided on a side thereof with a feeding portion 53 that is connected to a radio circuit provided in the substrate 50 but not shown in FIG. 10. The substrate 50 is provided on the upper face with a first conductive pattern 55 that is connected to the feeding portion 53.

As shown in FIG. 10, a portion of an area of the substrate 50 covered by the bend section 51 is formed to protrude upwards. The first conductive pattern 55 is provided partially on the protruding portion. Such a modification in which a face of the substrate 50 or the bend section 51 protrudes can diversify options of wiring of the conductive patterns.

FIG. 11 is a perspective view showing a configuration of an antenna device 6 of a third modification included in the fourth embodiment. The antenna device 6 has a substrate 60 and a bend section 61. The substrate 60 and the bend section 61 are formed by one planar flexible material. The bend section 61 is formed in such a way that an end portion of the substrate 60 formed similarly to the shape of the second embodiment shown in FIG. 5 is bent similarly to the shape shown in FIG. 4.

A distinction between the substrate 60 and the bend section 61, a definition of upper and lower faces of the substrate 60 and a definition of inner and outer faces of the bend section 61 are same as described with respect to the second embodiment. A front face of the bend section 61 shown in FIG. 11 crossing the substrate 60 is partially removed in the middle, though. Remaining portions on both sides of the removed portion indicated by diagonal hatching are bent towards the inside of the space surrounded by the bend section 61. Thus, the outer face of the portion of the bend section 61 indicated by the hatching is in contact with the upper face of the substrate 60.

The substrate 60 is provided on the upper face with a grounded conductor 62 (its shape shown in FIG. 11 is an example). The grounded conductor 62 is provided on a side thereof with a feeding portion 63 that is connected to a radio circuit provided in the substrate 60 but not shown in FIG. 11. The substrate 60 is provided on the upper face with a first conductive pattern 65 that is connected to the feeding portion 63. The first conductive pattern 65 extends from the upper face of the substrate 60 to the inner face of the bend section 61 and is open-ended.

As shown in FIG. 11, a coaxial cable is threaded through the one side of the removed portion of the bend section 61, and is connected to the feeding portion 63. The bend section 61 can be partially modified as described above so as to be applied as a guide for supporting a cable.

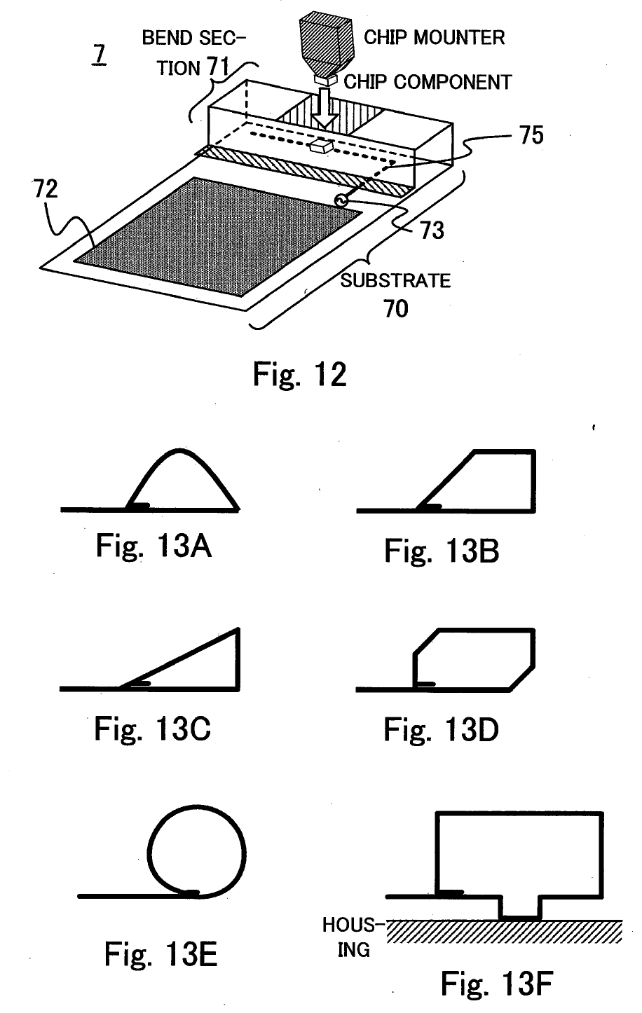

FIG. 12 is a perspective view showing a configuration of an antenna device 7 of a fourth modification included in the fourth embodiment. The antenna device 7 has a substrate 70 and a bend section 71. The substrate 70 and the bend section 71 are formed by one planar flexible material. The bend section 71 is formed in such a way that an end portion of the substrate 70 formed similarly as shown in FIG. 2 of the first embodiment is bent similarly as shown in FIG. 1.

A distinction between the substrate 70 and the bend section 71, a definition of upper and lower faces of the substrate 70 and a definition of inner and outer faces of the bend section 71 are same as described with respect to the first embodiment. An upper face of the bend section 71 shown in FIG. 12 being nearly parallel to the substrate 70 is partially removed in the middle, though. A portion of the bend section 71 indicated by diagonal hatching in FIG. 12 (corresponding to the portion of the bend section 11 of the first embodiment indicated by the diagonal hatching in FIGS. 1 and 2) is bent towards the outside of the space surrounded by the bend section 71 similarly as the first embodiment. Thus, the inner face of the portion of the bend section 71 indicated by the hatching is in contact with the upper face of the substrate 70.

The substrate 70 is provided on the upper face with a grounded conductor 72 (its shape shown in FIG. 12 is an example). The grounded conductor 72 is provided on a side thereof with a feeding portion 73 that is connected to a radio circuit provided in the substrate 70 but not shown in FIG. 11. The substrate 70 is provided on the upper face with a first conductive pattern 75 that is connected to the feeding portion 73.

As shown in FIG. 12, a chip mounter can be put through the portion removed from the bend section 71 so as to mount a chip component on the upper face of the substrate 70. The bend section 71 can be partially modified as described above so as to increase convenience for mounting components on the substrate 70.

FIGS. 13A-13F show other modifications of the bend sections or the substrates of the first to fourth embodiments described above as viewed from a right-hand side (in the same direction as shown in FIG. 3 or FIG. 6) in the perspective view of FIG. 1 and so on. FIG. 13A shows an example modified in such a way that the bend section is curved. FIG. 13B shows an example modified in such a way that the bend section is formed to be a trapezoid. FIG. 13C shows an example modified in such a way that the bend section is formed to be triangular. FIG. 13D shows an example modified in such a way that the bend section is formed to be a polygon. FIG. 13E shows an example modified in such a way that the bend section is rounded continuously from the substrate.

FIG. 13F shows an example modified in such a way that a portion of the substrate covered by the bend section protrudes downwards to be in contact with an inner face of a housing, and that other portions of the substrate and the bend section are separate from the housing. This configuration can arrange the conductive patterns provided on the bend section separate from the housing so as to reduce a wavelength shortening effect caused by dielectric material of the housing or an effect of dielectric loss caused by dielectric material of the housing.

According to the fourth embodiment of the present invention described above, the substrate and the bend section can be variously modified so as to expand applications and features of the present invention.

As described above with respect to the first to fourth embodiments, the bend section is formed by one planar flexible material with the substrate, and is formed in such a way that a portion including one end of the substrate is bent or rounded. The bend section is not limited to the above, and can be formed to be three-dimensional and separate from the substrate so as to be put on the upper face of the substrate. In that case, the material of the bend section may be same as or different from the material of the substrate.

In the above description of the embodiments and the modifications, the configurations, shapes and arrangements of the substrates and the bend sections, and the arrangements and connections of the conductive patterns are considered as exemplary only, and thus may be variously modified within the scope of the present invention.

The particular hardware or software implementation of the present invention may be varied while still remaining within the scope of the present invention. It is therefore to be understood that within the scope of the appended claims and their equivalents, the invention may be practiced otherwise than as specifically described herein.

What is claimed is

1. An electrical circuit material, comprising:
a substrate formed to be planar, the substrate having a first face and a second face being back to back each other, the first face being provided with a first conductive pattern; and
a bend section formed by a planar flexible material being bent or rounded and having a third face and a fourth face being back to back each other, the third face being provided with a second conductive pattern, the bend section being arranged with the substrate in such a way that a portion of the third face is in contact with the first face of the substrate and that the second conductive pattern is connected to the first conductive pattern.

2. The electrical circuit material of claim 1, wherein
the substrate and the bend section are formed by the same flexible material,
the bend section is formed by a portion of the substrate including an end of the substrate, the portion of the substrate being bent or rounded, and
the third face corresponds to an inner face of the bend section that continues from the first face of the substrate.

3. The electrical circuit material of claim 1, wherein
the substrate and the bend section are formed by the same flexible material,
the bend section is formed by a portion of the substrate including an end of the substrate, the portion of the substrate being bent or rounded, and
the third face corresponds to an outer face of the bend section that continues from the second face of the substrate.

4. The electrical circuit material of claim 1, wherein the flexible material is made from thermoplastic resin.

5. An antenna device, comprising:
a substrate formed to be planar, the substrate having a first face and a second face being back to back each other, the first face being provided with a feeding portion and a first conductive pattern connected to the feeding portion; and
a bend section formed by a planar flexible material being bent or rounded and having a third face and a fourth face being back to back each other, the third face being provided with a second conductive pattern, the bend section being arranged with the substrate in such a way that a portion of the third face is in contact with the first face of the substrate and that the second conductive pattern is connected to the first conductive pattern.

6. The antenna device of claim 5, wherein
the substrate and the bend section are formed by the same flexible material,
the bend section is formed by a portion of the substrate including an end of the substrate, the portion of the substrate being bent or rounded, and
the third face corresponds to an inner face of the bend section that continues from the first face of the substrate.

7. The antenna device of claim 5, wherein
the substrate and the bend section are formed by the same flexible material,
the bend section is formed by a portion of the substrate including an end of the substrate, the portion of the substrate being bent or rounded,
the third face corresponds to an inner face of the bend section that continues from the first face of the substrate, and
the first conductive pattern extends to the inner face of the bend section so as to form a multiple resonant antenna with the second conductive pattern.

8. The antenna device of claim 5, wherein
the substrate and the bend section are formed by the same flexible material,
the bend section is formed by a portion of the substrate including an end of the substrate, the portion of the substrate being bent or rounded, and
the third face corresponds to an outer face of the bend section that continues from the second face of the substrate.

9. The antenna device of claim 5, wherein
the substrate and the bend section are formed by the same flexible material,
the bend section is formed by a portion of the substrate including an end of the substrate, the portion of the substrate being bent or rounded,
the third face corresponds to an outer face of the bend section that continues from the second face of the substrate, and
the first conductive pattern extends to the inner face of the bend section so as to form a multiple resonant antenna with the second conductive pattern.

10. The antenna device of claim 5, wherein a portion of the bend section is removed.

11. The antenna device of claim 5, wherein the flexible material is made from thermoplastic resin.

12. A method for manufacturing an electrical circuit material, comprising:
providing a substrate formed to be planar with a bend section formed by a planar flexible material, the substrate having a first face and a second face being back to back each other, the first face being provided with a first conductive pattern, the bend section having a third face and a fourth face being back to back each other, the third face being provided with a second conductive pattern;
causing a portion of the third face to be in contact with the first face by bending or rounding the bend section; and
connecting the second conductive pattern to the first conductive pattern.

13. The method for manufacturing an electrical circuit material of claim 12, wherein
the substrate and the bend section are formed by the same flexible material,
the bend section is formed by a portion of the substrate including an end of the substrate, the portion of the substrate being bent or rounded, and
the third face corresponds to an inner face of the bend section that continues from the first face of the substrate.

14. The method for manufacturing an electrical circuit material of claim 12, wherein
the substrate and the bend section are formed by the same flexible material,
the bend section is formed by a portion of the substrate including an end of the substrate, the portion of the substrate being bent or rounded, and
the third face corresponds to an outer face of the bend section that continues from the second face of the substrate.
